(19) United States
(12) Patent Application Publication
(10) Pub. No.: US 2010/0103623 A1
(43) Pub. Date: Apr. 29, 2010

(54) LOW-TEMPERATURE-COFIRED-CERAMIC PACKAGE AND METHOD OF MANUFACTURING THE SAME

(76) Inventors: Changsoo Kwank, Daejeon-city (KR); Youn-Sub Noh, Daejeon-city (KR); Man-Seok Uhm, Daejeon-city (KR); In-Bok Yom, Daejeon-city (KR)

Correspondence Address: RABIN & Berdo, PC, 1101 14TH STREET, NW, SUITE 500, WASHINGTON, DC, 20005, US

(21) Appl. No.: 12/529,775

(22) PCT Filed: Mar. 12, 2008
(86) PCT No.: PCT/KR2008/001392

§ 371 Date: Sep. 3, 2009

(30) Foreign Application Priority Data
Apr. 26, 2007 (KR) 1020070040972

(51) Int. Cl. H05K 7/20; B32B 38/04

(52) U.S. Cl. 361/709; 361/707; 156/325; 156/252

(57) ABSTRACT

Provided are a low-temperature-cofired-ceramic (LTCC) package and a method of manufacturing the same. The LTCC package includes: an LTCC substrate including a plurality of LTCC layers and a recess in which a device is mounted; a thermal conductive element adhered onto a first LTCC layer exposed by the recess using a first thermal conductive adhesive member; the device adhered onto the thermal conductive element using a second thermal conductive adhesive member; and a connection member for electrically connecting the device with the LTCC substrate. In the LTCC package and the method, portions of the LTCC layers disposed under a high-heating device except a lowermost LTCC layer contacting a heat sink, which correspond to a thermal transmission path, are removed and replaced by a higher thermal conductive material to minimize heat dissipation resistance and heat resistance caused by thermal conduction. Thus, heat resistance and thermal stress between the bottom of the high-heating device and the heat sink can be minimized.

### CROSS-REFERENCE TO RELATED PATENT APPLICATION

This application claims the benefit of Korean Patent Application No. 10-2007-0040972, filed on Apr. 26, 2007, in the Korean Intellectual Property Office, the disclosure of which is incorporated herein in its entirety by reference.

### BACKGROUND OF THE INVENTION

1. Field of the Invention

The present invention relates to a low-temperature-cofired-ceramic (LTCC) package and a method of manufacturing the same, and more particularly, to a low-temperature-cofired-ceramic (LTCC) package having excellent heat dissipation characteristics and a method of manufacturing the same.

The present invention was supported by the Communications, Ocean and Meteorological Satellite program of the Ministry of Information and Communication (MIC) [project No. 2007-S-301, project title: Development of Satellite Communications System for Communications, Ocean and Meteorological Satellite].

2. Description of the Related Art

Low-temperature-cofired-ceramic (LTCC) technology allows devices to be integrated on a substrate and passive devises to be an LTCC module. Thus, electronic devices can be downscaled, and made lightweight and highly efficient.

According to the LTCC technology, a conventional printed circuit board (PCB) is replaced by a ceramic substrate, and passive devices, such as resistors, inductors, and capacitors, are formed in the ceramic substrate so that devices can be arranged 3-dimensionally. A circuit printing technique, such as a screen printing technique, and an etching technique used in semiconductor manufacturing processes can be applied to the LTCC technology. Also, the LTCC technology enables formation of a linewidth or interval of about 30 μm. Furthermore, since respective layers included in an LTCC package are fabricated using independent printing processes, highly precise patterns can be formed on the respective layers, thereby facilitating miniaturization of the electronic devices.

A conventional method of manufacturing an LTCC package is as follows. Initially, a green tape or a green sheet is formed using a mixture of a ceramic material and an organic material. The green sheet is cut to a desired size, and an alignment guide hole and a via hole are punched in the green sheet. The via hole is filled with a conductive material, and a desired interconnection circuit pattern is printed on the surface of the green sheet using a conductive paste formed of silver (Ag), copper (Cu), or ca combination thereof. Green sheets, which have undergone the printing process, are stacked in alignment with one another and compressibly adhered to one another at a temperature of about 60 to 80° C. under a pressure of about 10 to 50 MPa. The adhered green sheets are fired in a furnace, thereby obtaining an LTCC substrate. Then, devices are mounted on the LTCC substrate and undergo ordinary packaging processes, such as a wire-bonding process, thereby completing the manufacture of a semiconductor device.

An LTCC package generates heat due to the drive of a semiconductor device. When the heat is not externally dissipated but accumulated in the LTCC package, the characteristics of the LTCC package are degraded. A rise in the temperature of the LTCC package is due to heat generated by the drive of the semiconductor device, heat accumulated in an LTCC substrate, and heat accumulated in a heat sink. For example, when the semiconductor device is formed of gallium-arsenic (Ga-As), it has a thermal conductivity of about 30 to 40 W/m-K. While aluminum (Al), which is widely used for forming interconnection lines, has a thermal conductivity of about 170 W/m-K and pure Cu has a thermal conductivity of about 400 W/m-K, the LTCC substrate has a relatively low thermal conductivity of about 3 W/m-K. In particular, when a high-heating semiconductor device is manufactured as an LTCC package, a rise in the temperature of the LTCC package caused by heat accumulated in an LTCC substrate becomes problematic. As the number of layers of the LTCC substrate increases, the above-described problem becomes more serious.

Conventionally, in order to prevent accumulation of heat in an LTCC substrate, thermal vias are formed in a lower end of a semiconductor device, especially, a high-heating semiconductor device. Specifically, a hole is formed through the LTCC substrate to connect the lower end of the high-heating semiconductor device with a heat sink. Thereafter, the hole is filled with a paste containing a high thermal conductivity material, such as Ag, to form the thermal via. The thermal via may have a high thermal conductivity of about 290 W/m-K so it can increase the average thermal conductivity of the LTCC substrate.

FIG. 1 is a cross-sectional view of a conventional LTCC package 1.

Referring to FIG. 1, the LTCC package 1 includes an LTCC substrate 20 having a plurality of LTCC layers 20a, 20b, 20c, and 20d. The LTCC layer 20a, which is an uppermost layer of the LTCC substrate 20, includes a trench 22 in which a semiconductor device 10 is mounted. The semiconductor device 10 is mounted in the trench 22 and adhered to the LTCC substrate 20 using a first thermal conductive adhesive 30a. The semiconductor device 10 is electrically connected to the LTCC substrate 20 using a wire 34. A lower end of the LTCC substrate 20 is adhered to a heat sink 50 using a second thermal conductive adhesive 30b. The LTCC substrate 20 includes a plurality of thermal vias 40, which are formed through the LTCC layers 20b, 20c, and 20d. The thermal vias 40 are formed in positions corresponding to the bottom of the semiconductor device 10, and extend to the heat sink 50. Also, the thermal conductivity of the thermal vias 40 is typically about 100 times higher that of the LTCC layers 20a, 20b, 20c, and 20d. Thus, heat generated by the semiconductor device 10 is transmitted through the thermal vias 40 to the heat sink 50.

FIGS. 2A and 2B illustrate heat flux distributions obtained by modeling the LTCC package shown in FIG. 1 using a finite element method (FEM). In each of FIGS. 2A and 2B, a net shape is obtained by modeling the LTCC substrate using an FEM, and the length of a straight line extending from each element in a vertical direction is proportional to the heat flux of the element.

FIG. 2A shows a case where a heat source A is located among the thermal vias 40 included in the LTCC package. Heat emitted from the heat source A is transmitted through the four thermal vias 40 shown in FIG. 2A. However, heat is hardly transmitted at the heat source A.

FIG. 2B shows a case where a heat source B is located in the same position as a first thermal via 40a of the thermal vias 40 included in the LTCC package.

Heat emitted by the heat source B is mostly transmitted through the first thermal via 40a and comparatively less transmitted through second thermal vias 40b located around the heat source B. Thus, it can be seen that heat generated by the semiconductor device is mostly transmitted through the thermal vias 40.

For example, in a GaAs monolithic microwave integrated circuit (MMIC), most heat is generated in a field effect transistor (FET). A single FET occupies a very small area in the GaAs MMIC, so that heat generated by the FET is mostly transmitted through a very small portion of the surface of an LTCC substrate under the FET. That is, the LTCC substrate has very fine heat sources. However, since the LTCC substrate has a very low thermal conductivity, heat dissipation resistance caused by dissipation of heat from the heat source becomes very high, thus increasing a rise in the temperature of the GaAs MMIC.

If thermal vias of high thermal conductivity are formed in a lower end of the heat source, the heat dissipation resistance can be reduced. However, the size of the thermal vias and an interval between the thermal vias are limited thereto. Thus, a sectional area occupied by all the thermal vias is limited below 15.5% of the LTCC substrate so that the heat dissipation resistance can be reduced within a restricted range. Also, all heat generated by the FET is not transmitted through the thermal vias. Furthermore, a via paste for filling the thermal vias should have about the same coefficient of thermal expansion as LTCC layers in order to prevent damage caused by thermal stress. Therefore, there is a specific limit to increasing the thermal conductivity of the thermal vias.

In addition, when forming the thermal vias, the thermal vias may be incompletely filled with the via paste. Also, when excessively increasing the diameter of the thermal vias or excessively decreasing an interval between the thermal vias, a void may be formed between the via paste and the LTCC substrate during a firing process, thereby making the GaAs MMIC structurally weak. Also, when a too large number of thermal vias are formed, the LTCC substrate may weaken. Moreover, since a process of punching the thermal vias and a process of filling the thermal vias with the via paste are added, the manufacturing cost increases.

### SUMMARY OF THE INVENTION

The present invention provides a low-temperature-cofired-ceramic (LTCC) package, which is capable of efficiently dissipating heat generated by a semiconductor device mounted therein so that even a semiconductor device that generates a large amount of heat can be mounted in the LTCC package.

Also, the present invention provides a method of manufacturing an LTCC package in which heat generated by a semiconductor device mounted in the LTCC package can be efficiently dissipated so that even a semiconductor device that generates a large amount of heat can be mounted in the LTCC package.

According to an aspect of the present invention, there is provided an LTCC package including: an LTCC substrate including a plurality of LTCC layers and a recess in which a device is mounted; a thermal conductive element adhered onto a first LTCC layer exposed by the recess using a first thermal conductive adhesive member; the device adhered onto the thermal conductive element using a second thermal conductive adhesive member; and a connection member for electrically connecting the device with the LTCC substrate.

The thermal conductive element may include a lower thermal conductive element adhered to the first LTCC layer and an upper thermal conductive element disposed on the lower thermal conductive element, wherein the upper thermal conductive element may have a larger sectional area than the lower thermal conductive element. The lower thermal conductive element is located to transmit thermal energy generated by a heating portion of the device adhered to the upper thermal conductive element to a heat sink. The upper thermal conductive element and the lower thermal conductive element may be separately or integrally formed.

The LTCC package may further include a heat sink adhered to the opposite side of a side of the LTCC substrate to which the thermal conductive element is adhered using a third thermal conductive adhesive member. Also, the first LTCC layer may include one or more thermal vias formed therethrough. The thermal vias may include one of a silver (Ag) paste, a copper (Cu) paste, a combination thereof.

The thermal conductive element may include a metal. The metal may include copper (Cu), aluminum (Al), silver (Ag), gold (Au), or an alloy thereof. Each of the first, second, and third thermal conductive adhesive members may include Ag, Cu, or a combination thereof. The first, second, and third thermal conductive adhesive members may be formed of the same material. A pattern including an interconnection circuit, a passive device, or a combination thereof may be disposed on or in some or all of the LTCC layers of the LTCC substrate.

The heat sink may include a metal. The metal may include Cu, Al, Ag, Au, an alloy thereof, or stainless steel. Also, the heat sink may have a rough surface.

According to another aspect of the present invention, there is provided a method of manufacturing an LTCC package. The method includes: preparing a substrate including a plurality of LTCC layers and a recess in which a device is mounted; adhering a thermal conductive element onto a first LTCC layer exposed by the recess using a first thermal conductive adhesive member; adhering the device onto the thermal conductive element using a second thermal conductive adhesive member; and electrically connecting the device with the LTCC substrate using a connection member. The method may further include adhering a heat sink to the opposite side of a side of the LTCC substrate to which the thermal conductive element is adhered using a third thermal conductive adhesive member.

The method may further include covering the connection member with an encapsulant.

The preparation of the LTCC substrate may include forming a plurality of thermal vias through the first LTCC layer.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a conventional low-temperature-cofired-ceramic (LTCC) package;

FIGS. 2A and 2B illustrate heat flux distributions obtained by modeling the LTCC package shown in FIG. 1 using a finite element method (FEM);

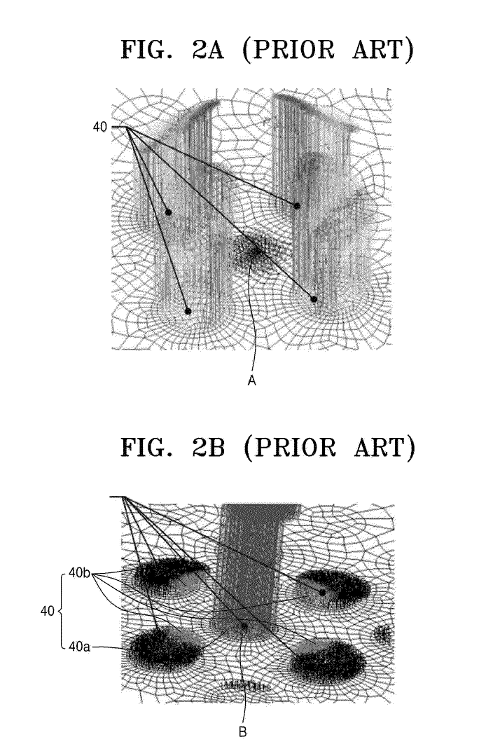

FIG. 3 is a cross-sectional view of an LTCC package according to an embodiment of the present invention;

FIG. 4 is a flowchart illustrating a method of manufacturing the LTCC package shown in FIG. 3;

FIG. 5 is a cross-sectional view of an LTCC package according to another embodiment of the present invention;

FIG. 6 is a cross-sectional view of an LTCC package according to yet another embodiment of the present invention; and

FIGS. 7A through 7C are images obtained by modeling the LTCC packages shown in FIGS. 1, 3, and 5 using an FEM.

### DETAILED DESCRIPTION OF THE INVENTION

The present invention will now be described more fully hereinafter with reference to the accompanying drawings, in which exemplary embodiments of the invention are shown. This invention may, however, be embodied in different forms and should not be construed as limited to the embodiments set forth herein. Rather, these embodiments are provided so that this disclosure is thorough and complete and fully conveys the scope of the invention to one skilled in the art. It will also be understood that when a layer is referred to as being “on” another layer or substrate, it can be directly on the other layer or substrate or intervening layers may also be present. In the drawings, the thicknesses of layers and regions are exaggerated for clarity. The same reference numerals are used to denote the same elements throughout the specification.

It will be understood that although the terms first and second are used herein to describe various members, devices, regions, layers, and/or sections, the members, devices, regions, layers and/or sections should not be limited by these terms.

These terms are only used to distinguish one member, device, region, layer or section from another member, device, region, layer or section. Thus, for example, a first member, device, region, layer, or section discussed below could be termed a second member, device, region, layer, or section without departing from the teachings of the present invention.

Hereinafter, related LTCC packages for improving heat dissipation characteristics and methods of manufacturing the same will be explained.

U.S. Patent Publication No. 20050236180 discloses a method of adding an LTCC layer formed of a high thermal conductivity material between an LTCC layer including an electronic circuit and a heat sink. In this method, although the thermal conductivity of the entire LTCC substrate may improve due to the added LTCC layer, the added LTCC layer has its proper heat resistance, thus causing a further rise in the temperature of an LTCC package.

U.S. Patent Publication No. 20060120058 discloses a method of directly adhering an LTCC substrate including LTCC layers to a heat sink instead of installing the LTCC substrate under a high-heating semiconductor device so that heat generated by the high-heating semiconductor device may not pass through the LTCC layers to reduce heat resistance. In this case, however, the high-heating semiconductor device must be located at a lowermost portion of the LTCC substrate.

Also, when the high-heating semiconductor device is adhered to the heat sink, the height of the high-heating semiconductor device must be accurately controlled to prevent occurrence of a contact failure between the high-heating semiconductor device and the LTCC substrate.

U.S. Pat. No. 5,386,339 introduces a method of partially removing an LTCC substrate located under a high-heating semiconductor device and filling the removed portion of the LTCC substrate with a high thermal conductivity material. However, according to this method, a large region of the LTCC substrate is removed and filled with a material having a different thermal characteristic, so that an LTCC package may be damaged due to a difference in coefficient of thermal expansion between the LTCC substrate and the high thermal conductivity material during a firing process. Also, when the LTCC substrate is not flattened to a sufficient extent, a gap may be formed between stacked layers of the LTCC substrate, and thus the thermal conductivity of the LTCC substrate is likely to greatly drop.

Also, U.S. Patent Publication No. 20040124002 provides with a method of forming a thermal dissipation plate under a high-heating semiconductor device and connecting the thermal dissipation plate with thermal vias. In this method, heat emitted by a small area of the high-heating semiconductor device is rapidly irradiated using the thermal radiation plate and transmitted through the thermal vias, thereby reducing heat dissipation resistance. However, since the thermal conductivity of an LTCC substrate disposed opposite the thermal dissipation plate cannot be improved, the entire thermal conductivity cannot be sufficiently elevated.

Various embodiments according to the present invention described below have the following common characteristics. Portions of a plurality of LTCC layers of an LTCC substrate, except a lowermost LTCC layer contacting a heat sink, corresponding to a region where a high-heating device is mounted are removed. Thereafter, a high thermal conductivity device is mounted on the removed portions of the LTCC layers. Thus, as compared with the conventional art in which thermal vias are formed in the LTCC substrate to dissipate heat, a sectional area used to transmit heat can be reduced, heat dissipation resistance can be reduced, and a material of higher thermal conductivity can be employed. As a result, heat resistance between the high-heating device and the heat sink can be reduced.

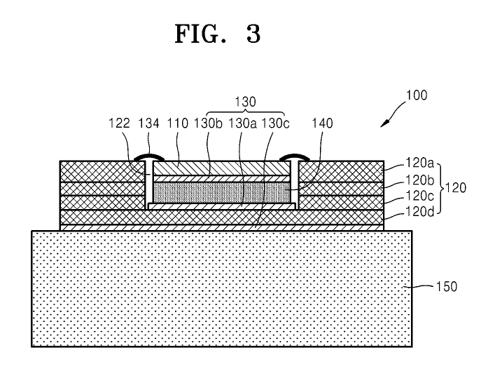

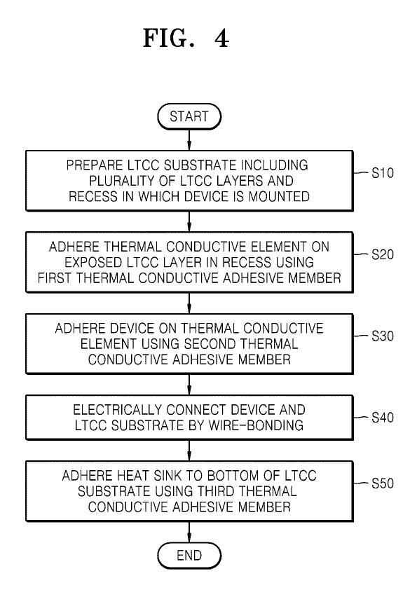

FIG. 3 is a cross-sectional view of an LTCC package 100 according to an embodiment of the present invention, and FIG. 4 is a flowchart illustrating a method of manufacturing the LTCC package 100 shown in FIG. 3.

Referring to FIG. 3, the LTCC package 100 includes an LTCC substrate 120, a thermal conductive element 140, a device 110, a wire 134, and a heat sink 150. The LTCC substrate 120 includes a plurality of LTCC layers 120a, 120b, 120c, and 120d. The thermal conductive element 140 is adhered to the bottom of a recess 122 of the LTCC substrate 120 using a first thermal conductive adhesive member 130a. The device 110 is adhered onto the thermal conductive element 140 using a second thermal conductive adhesive member 130b. The wire 134 is used to electrically connect the device 110 with the LTCC substrate 120. The heat sink 150 is adhered to the opposite side of a side of the LTCC substrate 120 on which the thermal conductive element 140 is disposed using a third thermal conductive adhesive member 130c.

Referring to FIGS. 3 and 4, an LTCC substrate 120 including the LTCC layers 120a, 120b, 120c, and 120d is prepared in operation S10. The LTCC layers 120a, 120b, 120c, and 120d are green sheets formed of a mixture of a ceramic material and an organic material. Each of the green sheets may have a thickness of about 0.1 mm or less, although the present invention is not so limited thereto. Each of the green sheets is cut to a desired size and an alignment guide hole (not shown) is punched in each of the green sheets. Also, holes in which the device 110 to be mounted in a subsequent process can be loaded are punched in the respective green sheets. A pattern (not shown) including an interconnection circuit or a passive device is formed on or in the green sheets having the holes. The green sheets are stacked in alignment with one another and compressibly adhered to one another by heating to form a single body. The interconnection circuit may be formed on, in, or through the green sheets and electrically connect the green sheets with one another. Also, the green sheets may further include passive devices, such as resistors, inductors, and capacitors.

The compressible adhesion of the green sheets may be performed at a temperature of, for example, 60 to 80° C., under a pressure of about 10 to 50 MPa. The above-described temperature and pressure conditions are only exemplary and the present invention is not limited thereto. The integrally formed green sheets are fired in a furnace to produce the LTCC substrate 120.

Referring again to FIG. 3, the LTCC substrate 120 includes the LTCC layers 120a, 120b, 120c, and 120d. The LTCC layers 120a, 120b, 120c, and 120d are stacked in alignment with one another. In particular, as described above, the holes in which the device 110 can be loaded are aligned with one another to form the recess 122. Here, a hole for the device 110 is not formed in the lowermost LTCC layer 120d of the LTCC layers 120a, 120b, 120c, and 120d. Thus, the lowermost LTCC layer 120d serves to support the device 110 mechanically. The recess 122 may be formed to a sufficient size to mount the device 110 therein. Also, four LTCC layers 120a, 120b, 120c, and 120d are illustrated in FIG. 3, but the present invention is not limited thereto and a smaller or larger number of LTCC layers may be provided.

In operation S20, the thermal conductive element 140 is adhered to the surface of the lowermost LTCC layer 120d, which is exposed by the recess 122, using the first thermal conductive adhesive member 130a. The thermal conductive element 140 may include a material having a high heat transfer coefficient so as to effectively dissipate heat generated by the device 110. The thermal conductive element 140 may include a metal, for example, copper (Cu), aluminum (Al), silver (Ag), gold (Au), or an alloy thereof. A gap between the thermal conductive element 140 inserted in the recess 122 and the recess 122 should be sufficiently wide. When the gap is too narrow, it is difficult to insert the thermal conductive element 140 in the recess 122. Also, when the first thermal conductive adhesive member 130a is excessively used, it is difficult to control the height of the thermal conductive element 140. The gap may be filled with an encapsulant later.

In operation S30, the device 110, for example, a semiconductor device, is adhered onto the thermal conductive element 140 using the second thermal conductive adhesive member 130b. The device 110 may be a high-heating device. FIG. 3 illustrates a single device 110 adhered onto the thermal conductive element 140, but the present invention is not limited thereto. In other words, a plurality of devices may be adhered onto the thermal conductive element 140, or the device 110 may include a plurality of stacked chips. As described above, a gap between the device 110 inserted in the recess 122 and the recess 122 should be sufficiently wide. When the gap is too narrow, it is difficult to insert the device 110 in the recess 122. Also, when the second thermal conductive adhesive member 130b is excessively used, it is difficult to control the height of the thermal conductive element 140. The gap may be filled with an encapsulant later.

In operation S40, the device 110 is electrically connected to the LTCC substrate 120 using the wire 134. As stated above, the device 110 may be externally connected by the interconnection circuits formed on, in, or through the

LTCC layers 120a, 120b, 120c, or 120d included in the LTCC substrate 120. The wire 134 is an example of a connection member for electrically connecting the device 110 with the LTCC substrate 120, and thus the present invention is not limited thereto. In operation S50, the heat sink 150 is adhered to the opposite side of a side of the lowermost LTCC layer 120d on which the device 110 is disposed using the third thermal conductive adhesive member 130c. The heat sink 150 externally dissipates heat transmitted from the device 110 through the thermal conductive element 140 and heat generated by the LTCC substrate 120. Thus, the heat sink 150 may include a material having a high heat transfer coefficient so as to effectively dissipate heat. The heat sink 150 may include a metal, for example, Cu, Al, Ag, an alloy thereof, or stainless steel. In order to increase a heat dissipation effect, the heat sink 150 may have a rough surface shape, for example, convex portions and concave portions, to increase a surface area. However, the heat sink 150 may or may not be installed in the present invention.

Each of the first, second, and third thermal conductive adhesive members 130a, 130b, and 130c may be an adhesive containing an Ag paste, Cu paste, or a combination thereof. Also, the first, second, and third thermal conductive adhesive members 130a, 130b, and 130c may be the same material. Also, the wire 134 may be optionally coated with an encapsulant. The encapsulant may be used to fill the gap between the thermal conductive element 140 and the recess 122 and between the device 110 and the recess 122.

In the above-described LTCC package 100, heat generated by the device 110 and heat generated by the LTCC substrate 120 are transmitted through the thermal conductive element 140 to the heat sink 150 and externally dissipated. In particular, even if heat is locally generated by the device 110, the heat is dissipated over a large area due to the thermal conductive element 140 of high thermal conductivity, so that the lowermost LTCC layer 120d has a relatively uniform temperature gradient and is heated to a small extent, thereby reducing thermal stress.

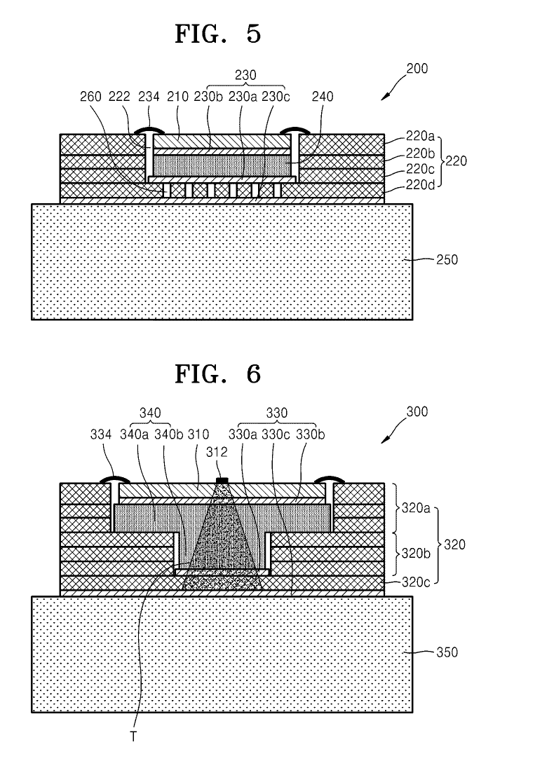

FIG. 5 is a cross-sectional view of an LTCC package 200 according to another embodiment of the present invention. For brevity, the same description as in the previous embodiment will not be presented here.

Referring to FIG. 5, the LTCC package 200 includes an LTCC substrate 220, a thermal conductive element 240, a device 210, a wire 234, and a heat sink 250.

The LTCC substrate 220 includes a plurality of LTCC layers 220a, 220b, 220c, and 220d. The thermal conductive element 240 is adhered to the bottom of a recess 222 of the LTCC substrate 220 using a first thermal conductive adhesive member 230a. The device 210 is adhered onto the thermal conductive element 240 using a second thermal conductive adhesive member 230b. The wire 234 is used to electrically connect the device 210 with the LTCC substrate 220. The heat sink 250 is adhered to the opposite side of a side of the LTCC substrate 220 on which the thermal conductive element 240 is disposed using a third thermal conductive adhesive member 230c.

As compared with the LTCC package 100 shown in FIG. 3, the LTCC package 200 according to the current embodiment is structured such that a lowermost LTCC layer 220d of the LTCC substrate 220 includes one or more thermal vias 260. A process of forming the thermal vias 260 is as follows. Holes corresponding to the thermal vias 260 are punched during a process of punching holes in green sheets that were described in the previous embodiment. The holes are filled with a paste containing a high thermal conductivity material, such as Ag, Cu, or a combination thereof, to form the thermal vias 260. The thermal vias 260 may have a thermal conductivity of, for example, 290 W/m-K or lower, so that the average thermal conductivity of the LTCC substrate 220 can be improved.

As described in the previous embodiment, since heat can be dissipated over a large area of the lowermost LTCC layer 220d due to the thermal conductive element 240, the lowermost LTCC layer 220d can have a relatively uniform temperature gradient and be heated to a small extent. In the LTCC package 200 according to the present embodiment, heat can be transmitted to the heat sink 250 more rapidly through the thermal vias 260, thereby further reducing heat resistance.

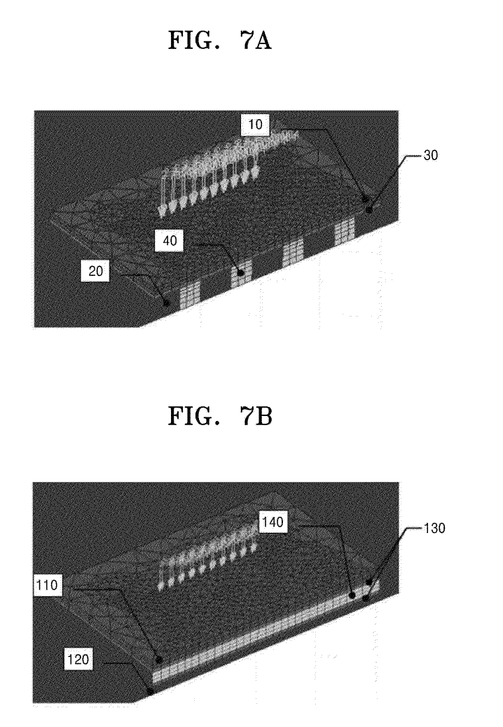

FIG. 6 is a cross-sectional view of an LTCC package 300 according to yet another embodiment of the present invention. For brevity, the same description as in the previous embodiment will not be presented here.

Referring to FIG. 6, the LTCC package 300 includes an LTCC substrate 320, a thermal conductive element 340, a device 310, a wire 334, and a heat sink 350. The LTCC substrate 320 includes a plurality of LTCC layers 320a, 320b, and 320c. The thermal conductive element 340 is adhered to the bottom of a recess 322 of the LTCC substrate 320 using a first thermal conductive adhesive member 330a. The device 310 is adhered onto the thermal conductive element 340 using a second thermal conductive adhesive member 330b. The wire 334 is used to electrically connect the device 310 with the LTCC substrate 320. The heat sink 350 is adhered to the opposite side of a side of the LTCC substrate 320 on which the thermal conductive element 340 is disposed using a third thermal conductive adhesive member 330c.

The LTCC package 300 according to the current embodiment includes the device 310 with a larger size than in the case of the previous embodiments, so that the shape of the thermal conductive element 340 is changed considering a thermal conductive path T of a high-heating portion 312 included in the device 310.

Specifically, when the device 310 has the larger size and the LTCC layers 320a and 320b are partially removed in the same manner as described in the previous embodiments with reference to FIGS. 3 and 5, very large portions of the LTCC layers 320a and 320b are removed, and thus the entire structure of the LTCC substrate 320 weakens. The LTCC package 100 shown in FIG. 3 may be structurally vulnerable because the thermal conductive element 140 and the device 110 are supported only by the lowermost LTCC layer 120d. By comparison, the LTCC package 300 shown in FIG. 6 may be structurally stable because the thermal conductive element 340 and the device 310 are supported not only by a lowermost LTCC layer 320c but also by an intermediate LTCC layer 320b. Also, the thermal conductive element 340 inserted into the recess 322 may include a large amount of Ag or Cu, thereby increasing the manufacturing cost.

Therefore, as shown in FIG. 6, the shape of the thermal conductive element 340 is changed to correspond to the thermal conductive path T of the high-heating portion 312. Heat is transmitted due to oscillation of electrons and phonons of a transmissive medium and mostly radiated in a radial manner. When the device 310 shown in FIG. 6 has a relatively large size, the height of the thermal conductive element 340 is less than the width thereof, and thus a large amount of heat moves downward. Accordingly, it can be assumed that heat generated by the high-heat portion 312 of the device 310 is mostly transmitted along the thermal conductive path T. Therefore, the thermal conductive element 340 can be transformed to include the thermal conductive path T. FIG. 6 illustrates an example of the thermal conductive element 340, which includes an upper thermal conductive element 340a and a lower thermal conductive element 340b having a smaller sectional area than the upper thermal conductive element 340a. The upper and lower thermal conductive elements 340a and 340b may be formed of the same material. Also, the upper and lower thermal conductive elements 340a and 340b may be separately formed and adhered to each other or integrally formed. Also, as described in the second embodiment, the lowermost LTCC layer 320c may include one or more thermal vias to increase a thermal transmission effect. Herein, the meaning of the word “lower” in terms of the lower thermal conductive elements 340b is not regarding the level of thermal conductivity, but refers to the relatively low position of the thermal conductive elements 340b.

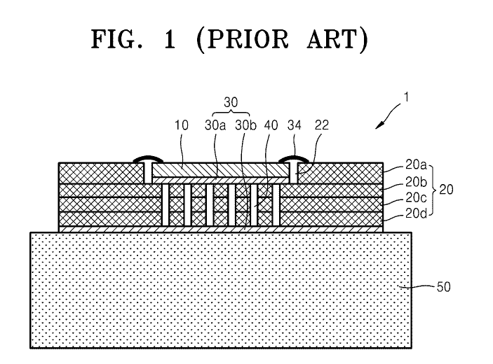

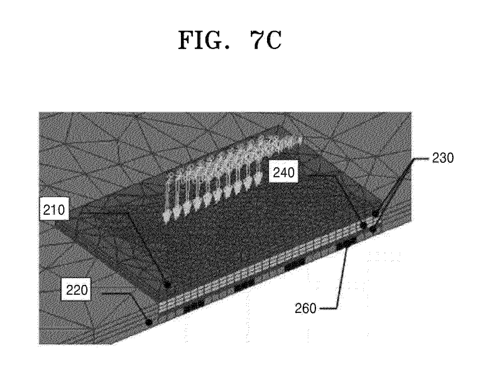

FIGS. 7A through 7C are images obtained by modeling a conventional LTCC package and LTCC packages according to the present invention using a finite element method (FEM) in order to make a thermal analysis of the LTCC packages according to the present invention. Specifically, FIG. 7A is a modeling image of the conventional LTCC package 1 shown in FIG. 1, FIG. 7B is a modeling image of the LTCC package 100 shown in FIG. 3, according to the present invention, and FIG. 7C is a modeling image of the LTCC package 200 shown in FIG. 5, according to the present invention.

Referring to FIGS. 7A through 7C, it is assumed that via pastes for filling the thermal vias 40 and 260 have a thermal conductivity of about 289 W/m-K, the LTCC substrates 20, 120, and 220 have a thermal conductivity of about 3.3 W/m-K, the thermal conductive adhesive members 30, 130, and 230 have a thermal conductivity of about 57 W/m-K, and the thermal conductive elements 140 and 240 have a thermal conductivity of about 401 W/m-K comparable to that of high-purity Cu. Also, the thermal conductivity of the devices 10, 110, and 210 is equal to that of GaAs, which varies with temperature. It is assumed that the thermal vias 40 and 260 have a diameter of 0.3 mm and a pitch of 0.75 mm, which are obtained when the thermal vias 40 and 260 are of highest density. Also, it is assumed that each LTCC layer of the LTCC substrates 20, 120, and 220 is about 0.1 mm in thickness, each of the devices 10, 110, and 210 is about 0.1 mm in thickness, and each of the thermal conductive adhesive members 30, 130, and 230 is about 0.05 mm in thickness. In addition, it is assumed that the bottom of the lowermost LTCC layer of each of the LTCC substrates 20, 120, and 220 has a temperature of about 55° C.

The following analysis result is obtained based on the modeling images of FIGS. 7A through 7C. Initially, when heat is generated, the conventional LTCC package 1 shown in FIG. 1 is heated up to a temperature of about 66° C., the LTCC package 100 shown in FIG. 3 is heated up to a temperature of about 50° C., and the LTCC package 200 shown in FIG. 5 is heated up to a temperature of about 41° C. In comparison with the heat resistance of the conventional LTCC package 1, the heat resistance of the LTCC package 100 shown in FIG. 3 was reduced by 24%, and the heat resistance of the LTCC package 200 shown in FIG. 5 was reduced by 38%. As the number of the LTCC layers disposed under the device 10, 110, or 210 increases, a reduction in heat resistance increases. For example, six LTCC layers are formed under each of the devices 10, 110, and 210 instead of three LTCC layers, the conventional LTCC package 1 is heated up to a temperature of 73° C., while the temperatures of the LTCC packages 100 and 200 according to the present invention are slightly different when only three LTCC layers are formed, irrespective of absence or presence of the thermal vias 260. Therefore, in this case, the heat resistance of the LTCC package 200 was reduced by as much as 44%, compared with that of the conventional LTCC package 1.

According to the present invention as described above, portions of LTCC layers disposed under a high-heating device except a lowermost LTCC layer contacting a heat sink, which correspond to a thermal transmission path, are removed and replaced by a higher thermal conductive material to minimize heat dissipation resistance and heat resistance caused by thermal conduction. As a result, heat resistance and thermal stress between the bottom of the high-heating device and the heat sink can be minimized. As a consequence, a rise in the temperature of an LTCC package can be minimized, and a process of forming thermal vias may be omitted, thereby reducing the manufacturing time and cost.

While the present invention has been particularly shown and described with reference to exemplary embodiments thereof, it will be understood by one of ordinary skill in the art that various changes in form and details may be made therein without departing from the spirit and scope of the present invention as defined by the following claims.

What is claimed is:

1. A low-temperature-cofired-ceramic (LTCC) package comprising:
an LTCC substrate including a plurality of LTCC layers and a recess in which a device is mounted;
a thermal conductive element adhered onto a first LTCC layer exposed by the recess using a first thermal conductive adhesive member;
the device adhered onto the thermal conductive element using a second thermal conductive adhesive member; and
a connection member for electrically connecting the device with the LTCC substrate.

2. The LTCC package of claim 1, wherein the thermal conductive element comprises a lower thermal conductive element adhered to the first LTCC layer and an upper thermal conductive element disposed on the lower thermal conductive element, the upper thermal conductive element having a larger sectional area than the lower thermal conductive element.

3. The LTCC package of claim 1, further comprising a heat sink adhered to the opposite side of a side of the LTCC substrate to which the thermal conductive element is adhered using a third thermal conductive adhesive member.

4. The LTCC package of claim 2, wherein the upper thermal conductive element and the lower thermal conductive element are separately or integrally formed.

5. The LTCC package of claim 1, wherein the first LTCC layer comprises one or more thermal vias formed therethrough.

6. The LTCC package of claim 5, wherein the thermal vias comprise one of a silver (Ag) paste, a copper (Cu) paste, and a combination thereof.

7. The LTCC package of claim 1, wherein the top of the device is at the same level with or at a lower level than the top of the LTCC substrate.

8. The LTCC package of claim 1, wherein the device is a high-heating device.

9. The LTCC package of claim 1, wherein the thermal conductive element comprises a metal.

10. The LTCC package of claim 9, wherein the metal comprises one selected from the group consisting of copper (Cu), aluminum (Al), silver (Ag), gold (Au), and an alloy thereof.

11. The LTCC package of claim 1, wherein each of the first, second, and third thermal conductive adhesive members comprise one selected from the group consisting of Ag, Cu, and a combination thereof.

12. The LTCC package of claim 1, wherein the first, second, and third thermal conductive adhesive members are formed of the same material.

13. The LTCC package of claim 1, wherein a pattern including an interconnection circuit, a passive device, or a combination thereof is disposed on or in some or all of the LTCC layers of the LTCC substrate.

14. The LTCC package of claim 3, wherein the heat sink comprises a metal.

15. The LTCC package of claim 14, wherein the metal comprises one selected from the group consisting of Cu, Al, Ag, Au, an alloy thereof, and stainless steel.

16. The LTCC package of claim 3, wherein the heat sink has a rough surface.

17. A method of manufacturing a low-temperature-cofired-ceramic (LTCC) package, the method comprising:
preparing a substrate including a plurality of LTCC layers and a recess in which a device is mounted;
adhering a thermal conductive element onto a first LTCC layer exposed by the recess using a first thermal conductive adhesive member;
adhering the device onto the thermal conductive element using a second thermal conductive adhesive member; and
electrically connecting the device with the LTCC substrate using a connection member.

18. The method of claim 17, further comprising adhering a heat sink to the opposite side of a side of the LTCC substrate to which the thermal conductive element is adhered using a third thermal conductive adhesive member.

19. The method of claim 17, further comprising covering the connection member with an encapsulant.

20. The method of claim 17, wherein the preparing of the LTCC substrate comprises forming a plurality of thermal vias through the first LTCC layer.
